(19) United States
(12) Patent Application Publication
(10) Pub. No.: US 2010/0254489 A1
(43) Pub. Date: Oct. 7, 2010

(54) CODE ENHANCED STAGGERCASTING

(75) Inventor: Richard W. Citta, Oak Park, IL (US)

Correspondence Address: Robert D. Shedd, Patent Operations;THOMSON Licensing LLC, P.O. Box 5312, Princeton, NJ, 08543-5312, US

(73) Assignee: Thomson Licensing

(21) Appl. No.: 12/734,407

(22) PCT Filed: Nov. 14, 2008
(86) PCT No.: PCT/US2008/012795

§ 371 Date: Apr. 28, 2010

Related U.S. Application Data
(60) Provisional application No. 61/003,047, filed on Nov. 14, 2007.
(60) Provisional application No. 61/002,977, filed on Nov. 14, 2007.

(51) Int. Cl. H04L 27/00; H03K 9/00

(52) U.S. Cl. 375/299; 375/316

(57) ABSTRACT

A method and architecture for processing signal communications between an encoder and decoder operating according to the ATSC standard adapted for mobile handheld transmission is disclosed. The method and apparatus comprises transmitting a packet and a redundant packet according to spatial, time and frequency diversity to enhance the redundancy error processing.

### PRIORITY CLAIM

This application claims the benefit of U.S. Provisional Patent Application No. 61/003,041 entitled “Code Enhanced Staggercasting” and No. 61/002,977 entitled “ATSC M/H Mobile Broadcast for Portable Services”, which are incorporated herein by reference.

### FIELD OF THE INVENTION

The present invention relates to transmitting data in a multimode transmission system. In particular, the present invention relates to a transmission system wherein multiple code rates can be used in data transmission within a single standard transmission protocol, such as ATSC.

### BACKGROUND OF THE INVENTION

Over the past decades, video transmission systems have migrated from analog to digital formats. In the United States, broadcasters are in the final stages of completing the switch from the National Television System Committee (NTSC) analog television system, to the Advanced Television Systems Committee (ATSC) A/53 digital television system. The A/53 standard provides “specification of the parameters of the system including the video encoder input scanning formats and the preprocessing and compression parameters of the video encoder, the audio encoder input signal format and the pre-processing and compression parameters of the audio encoder, the service multiplex and transport layer characteristics and normative specifications, and the VSB RF/Transmission subsystem.” The A/53 standard defines how source data (e.g., digital audio and video data) should be processed and modulated into a signal that is to be transmitted over the air. This processing adds redundant information to the source data so that a receiver may recover the source data even if the channel adds noise and multi-path interference to the transmitted signal. The redundant information added to the source data reduces the effective rate at which the source data is transmitted, but increases the potential for successful recovery of the source data from a received signal.

The ATSC A/53 standard development process was focused on HDTV and fixed reception. The system was designed to maximize video bit rate for the large high resolution television screens that were already beginning to enter the market. Transmissions broadcast under the ATSC A/53 standard, however, present difficulties for mobile receivers. Enhancements to the standard are required for robust reception of digital television signals by mobile devices.

Recognizing this fact, in 2007, the ATSC announced the launch of a process to develop a standard that would enable broadcasters to deliver television content and data to mobile and handheld devices via their digital broadcast signal. Multiple proposals were received in response. The resulting standard, to be called ATSC-M/H, is intended to be backwards compatible with ATSC A/53, allowing operation of existing ATSC services in the same RF channel without an adverse impact on existing receiving equipment.

Many systems for transmission to mobile devices, such as some proposed ATSC-M/H systems, perform periodic transmission. Such systems can include a preamble in their transmissions in order to assist with receiver system operation. Preambles typically include known information that portions of the receiving system may use for training to improve reception, which can be particularly useful in difficult environments such as those found in mobile operation. Such systems may further encode data at differing code rates. The code rate or information rate of a forward error correction (FEC) code, for example a convolutional code, states what portion of the total amount of information that is non redundant. The code rate is typically a fractional number. If the code rate is k/n, for every k bits of useful information, the coder generates totally n bits of data, of which n−k are redundant.

The existing ATSC M/H proposal includes the use of separable block codes to allow for code-enhanced time and frequency diversity. In the example of a ½ rate coded transmission, the mobile data is input into a FEC coder which outputs 2 bytes for each input byte. The two bytes represent the original data and redundant data. A receiver can receive either the original data or the redundant data at the receiver threshold of the original data. If both streams are received there is a coding gain advantage so that the receiver will recover the data at a threshold below the original data. Mobile and pedestrian operation of communications equipment pose some of the greatest challenges, with extreme transmission channel impairments present due to buildings and moving vehicles as well as other impairments. A system of providing data in a redundant manner may be used. It would be desirable to take advantage of the redundant information through frequency, time and special diversity to improve reception on mobile devices.

### SUMMARY OF THE INVENTION

In accordance with an aspect of the present invention, a method

In accordance with another aspect of the present invention a method

### DESCRIPTION OF THE DRAWINGS

FIG. 1 is a block diagram of an embodiment of a terrestrial broadcast transmitter for mobile/handheld reception of the present disclosure;

FIG. 2 is a block diagram of an embodiment of a portion of an exemplary mobile/handheld data stream of the present disclosure;

FIG. 3 is a block diagram of an embodiment of an exemplary data frame of the present disclosure;

FIG. 4 is a block diagram of an embodiment of a terrestrial broadcast receiver for mobile/handheld reception of the present disclosure;

FIG. 5 is a block diagram of an embodiment of a decoder of the present disclosure;

FIG. 6 is a block diagram of another embodiment of a decoder of the present disclosure;

FIG. 7 is a block diagram of a terrestrial broadcast environment according to the present invention;

FIG. 8, is a block diagram of an embodiment of a portion of a transmitter according to the present disclosure.

The exemplifications set out herein illustrate preferred embodiments of the invention, and such exemplifications are not to be construed as limiting the scope of the invention in any manner.

### DESCRIPTION OF THE PREFERRED EMBODIMENT

As described herein, the present invention provides a method and apparatus for transmitting data in a mobile broadcast system utilizing diversity and data redundancy, such as a proposed ATSC-M/H system, while allowing backward compatibility with legacy transmission and reception paths, such as ATSC A/53. While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims. For instance, the described technique could be applicable to transmission systems designed for other types of data or that use different coding, error-correction, redundancy, interleaving, or modulation schemes.

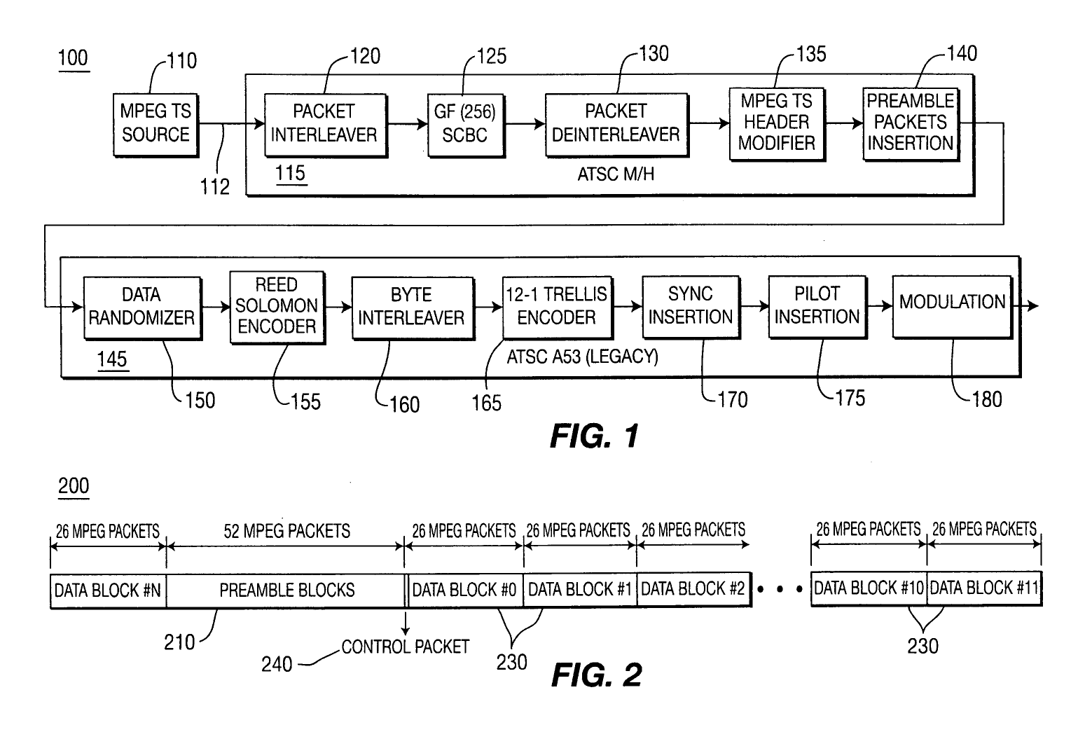

Referring now to the drawings, and more particularly to FIG. 1, a block diagram of an embodiment of a terrestrial broadcast transmitter for mobile/handheld reception of the present disclosure is shown. Embodiment 100 of FIG. 1 comprises a plurality of signal transmitting means such as an MPEG Transport stream source 110, an ATSC M/H preprocessing path 115, and a legacy ATSC A/53 processing path. The elements within the ATSC-M/H preprocessing 115 comprise a packet interleaver 120, a serial concatenated block coder 125, a packet deinterleaver 130, an MPEG transport stream header modifier 135, a preamble packet inserter 140. The legacy ATSC A/53 processing path 145 comprises a data randomizer 150, a reed Solomon encoder 155, a byte interleaver 160, a trellis encoder 165, a sync inserter 170, a pilot inserter 175 and a modulator 180.

In the ATSC-M/H preprocessing flow, incoming MPEG transport data 112 from an MPEG transport stream source 110 is received at the packet interleaver 120. The packet interleaver 120 rearranges a sequenced number of bytes into a different sequence to improve bit error rate and frame error rate performance. In this exemplary embodiment, the packet interleaver 120 takes the bytes from a fixed number of consecutive packets in a row by row order, and outputs the bytes column by column. In this way, all of the first bytes of the packets are grouped together, all of the second bytes of the packets are grouped together, and so on until the last bytes of the packets. Each source packet is an MPEG transport stream packet with the sync byte removes, so each packet length is 187 bytes. The number of packets in each code frame is the same as the number of source symbols required for the GF(256) serial concatenated block code.

The interleaved data is then coupled to the Galois Field GF(256) serial concatenated block coder (SCBC) 125. The GF(256) Serial Concatenated Block Code (SCBC) 125 Decoder will take on different forms depending on the Rate Mode for the current symbols. In general, it consists of constituent decoders that iteratively decode soft information in a turbo decoding manner. The SCBC 125 codes the packet interleaved data in one of a plurality of forms depending on the desired data rate and the codeword length. The SCBC 125 consists of one or more constituent GF(256) codes cascaded in a serial fashion, linked by GF(256) code optimized block interleavers to improve overall code performance. This may be optionally followed by a GF(256) puncture to achieved desired codeword length.

Specifically, a Galois Field GF(pⁿ) is a mathematical set comprising a finite number of elements pⁿ where the values of p and n are integers. A particular Galois Field is defined using a generator polynomial g(x). Each element of the Galois Field may be represented by a unique bit pattern having n bits. Furthermore, a unique polynomial of degree pⁿ may be associated with each element where each coefficient of the polynomial is between 0 and p−1. Further, mathematical operations in the Galois Field have important properties. Addition of two elements of the Galois Field GF(pⁿ) is defined as an element associated with a polynomial that has coefficients that are the modulo-p sum of the coefficients of the polynomials associated with the two elements being added. Similarly, multiplication of two elements is defined as the multiplication of the polynomials associated with the two elements modulo the generator polynomial g(x) associated with the Galois Field. Addition and multiplication operators are defined over the Galois Field such that the sum and product of any two elements of the Galois Field are elements of the Galois Field. A property of the Reed-Solomon codeword is that multiplying each byte of the codeword by an element of the Galois Field results in another valid Reed-Solomon codeword. Furthermore, byte-by-byte addition of two Reed-Solomon codewords produces another Reed-Solomon codeword. The legacy A53 standard defines a 256 element Galois Field GF(2⁸) and the associated generator polynomial g(x) for use in the Reed-Solomon algorithm. The properties of the Galois Field also create the ability to generate syndromes for the codewords in order to determine errors. Another important property of the codeword.

In an exemplary embodiment, two codewords or packets are generated by a rate ½ byte-code encoder include a duplicate of the originally input codeword and a new codeword that provides redundancy to the original codeword. The two codewords may also be described as systematic data and non-systematic data. It is important to note that the codewords representing systematic and non-systematic data may be arranged to form larger data structures. In a preferred embodiment, the codewords may be organized to form a rugged data stream of data packets. The rugged data stream includes systematic packets, which are duplicates of the data packets in a stream portion A, and non-systematic packets generated by the processing of a byte-code encoder in a stream portion A′. Non-systematic packets also include packets that may be derived from other systematic and non-systematic packets of the rugged data stream. Further, the packets in the rugged data stream may be further composed of systematic bytes and non-systematic bytes. In such embodiments, a systematic byte is a duplicate of byte of content data and a non-systematic byte is one that is derived from other systematic and non-systematic bytes.

The redundant or non-systematic codeword or packet output by a byte-code encoder is the result of multiplying each byte of the incoming codeword or packet by an element b of the Galois Field GF(256). In one embodiment, if the MPEG transmission source 110 generate a message M, which is comprised of bytes M(1), M(2), . . . , M(187), where M(1) is the first byte of the message, M(2) is the second byte of the message, etc., then subsequently, the byte-code encoder 104 produces the codewords A and A′ from the codeword M, as follows:

A(i)=M(i) i=1, 2, . . . , 187 (1)

A′(i)=b*M(i) i=1, 2, . . . , 187 (2)

The value b is a predetermined (non-zero) element of the same Galois Field GF(256) that may used by the Reed-Solomon encoder 155. In an illustrative embodiment, the value of the b element is 2. It should be apparent that using the same Galois Field for both the byte-code encoder and the Reed-Solomon encoder allows operations between the two encoders based on the properties of the Galois Field. Byte-code encoder 125 encodes all of the bytes of the data packet, including the bytes that form the header containing the PID, to generate one or more non-systematic packets of the rugged data stream. Thus, the PID of each non-systematic packet is byte-code encoded and may no longer represent a PID value that is recognizable to a receiving device.

It should be apparent that any packets encoded by the embodiment of the transmitter depicted by encoder 100 may be decoded by an embodiment of a decoder used in a legacy receiver that complies with the A53 standard. The decoder in a legacy receiver provides packets of the rugged data stream to a data decoder. The rugged data stream includes non-systematic packets that are encoded using a byte-code encoder that will be decoded correctly by a decoder in a legacy receiver, but will result in data content that is unrecognizable by the legacy receiver. However, because such packets have a PID that is not associated in the Program Map Table (PMT) with an existing or legacy data format, the content decoder in a legacy receiver ignores these non-systematic packets of the rugged data stream.

Byte-code encoder 125 uses equation (2) above to generate a non-systematic packet for each systematic packet and provides both packets to the legacy 8-VSB encoder for transmission to produce an encoded stream with an effective data rate of ½ (that is, 1 byte in, 2 bytes out). As mentioned earlier, byte code encoder 125 may be capable using other encoding rates to produce other effective data rates. In some embodiments, the byte-code encoder may produce one byte-encoded packet for every two source packets, M_{A} and M_{B}, received from the MPEG TS Source 110 to generate a rate 2/3 rugged data stream comprising the two systematic packets and one non-systematic packet calculated as follows:

M_{AB}(i)=M_{A}(i)*b₁+M_{B}(i)*b₂ i=1, 2, . . . , 187 (3)

where M_{A} and M_{B} are consecutive systematic packets produced by the data generator 102 and b₁ and b₂ are predetermined elements of a Galois Field, such as the Galois Field used by the Reed-Solomon encoder 155. In an illustrative embodiment, the value of the b₁ and b₂ elements is 2. In some embodiments, the values of b₁ and b₂ may not be identical. The byte-code encoder 125 provides the packets M_{A}, M_{B}, and M_{AB} to the legacy 8-VSB encoder 130 for further encoding and transmission.

Byte-code encoder 125 may use different coding rates to produce rugged data streams (i.e., ones having lower data rates) by including additional input data packets for generating the redundant packets. Another embodiment of the byte-code encoder 125 produces a rate 4/9 data stream by employing four systematic packets M_{A}, M_{B}, M_{c}, and M_{D} from MPEG TS Source 110 and 5 non-systematic packets calculated as follows:

M_{AB}(i)=M_{A}(i)*b₁+M_{B}(i)*b₂ i=1, 2, . . . , 187 (4)

M_{CD}(i)=M_{C}(i)*b₃+M_{D}(i)*b₄ i=1, 2, . . . , 187 (5)

M_{AC}(i)=M_{A}(i)*b₅+M_{C}(i)*b₆ i=1, 2, . . . , 187 (6)

M_{BD}(i)=M_{B}(i)*b₇+M_{D}(i)*b₈ i=1, 2, . . . , 187 (7)

M_{ABCD}(i)=M_{AB}(i)*b₉+M_{CD}(i)*b₁₀ i=1, 2, . . . , 187 (8)

The values b₁, b₂, . . . , b₁₀ are predetermined elements selected from the Galois Field. In an illustrative embodiment, the values for b₁, b₂, . . . , b₁₀ are 2. In addition, as shown in equation (8), the packet M_{ABCD} is a redundant packet generated from other redundant packets only, specifically packets M_{AB} and M_{CD}. It should be apparent that the redundant packet M_{ABCD} may be alternately generated using the elements of the redundant packets M_{AC} and M_{BC}. In some embodiments of the MPEG transmission source generator 110, elimination of one or more non-systematic packets may be performed in an operation known as puncturing. For instance, a punctured rate 4/8 may be produced by not generating one of the packets that would have employed only redundant packets (i.e., M_{ABCD} in this case) because this packet contains the smallest amount of intrinsic data. Any packet or codeword may be removed. However, removal of a packet or codeword containing the smallest amount of intrinsic data may be optimal. Code puncturing may be used to change the number of transmitted packets in order to meet certain limitations on number of packets or codewords transmitted.

Further, byte-code encoder 125 may also produce a rugged data stream that has a data rate of 8/27 by employing 8 data packets M_{A}, M_{B}, . . . , M_{H} to produce 19 non-systematic packets, as follows:

M_{AB}(i)=M_{A}(i)*b₁+M_{B}(i)*b₂ (9)

M_{CD}(i)=M_{C}(i)*b₃+M_{D}(i)*b₄ i=1, 2, . . . , 187 (10)

M_{AC}(i)=M_{A}(i)*b₅+M_{C}(i)*b₆ i=1, 2, . . . , 187 (11)

M_{BD}(i)=M_{B}(i)*b₇+M_{D}(i)*b₈ i=1, 2, . . . , 187 (12)

M_{ABCD}(I)=M_{AB}(i)*b₉+M_{CD}(i)*b₁₀ i=1, 2, . . . , 187 (13)

M_{EF}(i)=M_{E}(i)*b₁₁+M_{F}(i)*b₁₂ i=1, 2, . . . , 187 (14)

M_{GH}(i)=M_{G}(i)*b₁₃+M_{H}(i)*b₁₄ i=1, 2, . . . , 187 (15)

M_{EG}(i)=M_{E}(i)*b₁₅+M_{G}(i)*b₁₆ i=1, 2, . . . , 187 (16)

M_{FH}(i)=M_{F}(i)*b₁₇+M_{H}(i)*b₁₈ i=1, 2, . . . , 187 (17)

M_{EFGH}(i)=M_{EF}(i)*b₁₉+M_{GH}(i)*b₂₀ i=1, 2, . . . , 187 (18)

M_{AE}(i)=M_{A}(i)*b₂₁+M_{E}(i)*b₂₂ i=1, 2, . . . , 187 (19)

M_{BF}(i)=M_{B}(i)*b₂₃+M_{F}(i)*b₂₄ i=1, 2, . . . , 187 (20)

M_{CG}(i)=M_{C}(i)*b₂₅+M_{G}(i)*b₂₆ i=1, 2, . . . , 187 (21)

M_{DH}(i)=M_{D}(i)*b₂₇+M_{H}(i)*b₂₈ i=1, 2, . . . , 187 (22)

M_{ACEG}(i)=M_{AC}(i)*b₂₉+M_{EG}(i)*b₃₀ i=1, 2, . . . , 187 (23)

M_{BDFH}(i)=M_{BD}(i)*b₃₁+M_{FH}(i)*b₃₂ i=1, 2, . . . , 187 (24)

M_{ABEF}(i)=M_{AB}(i)*b₃₃+M_{EF}(i)*b₃₄ i=1, 2, . . . , 187 (25)

M_{CDGH}(i)=M_{CD}(i)*b₃₅+M_{GH}(i)*b₃₆ i=1, 2, . . . , 187 (26)

M_{ABCDEFGH}(i)=M_{ABCD}(i)*b₃₇+M_{EFGH}(i)*b₃₈ i=1, 2, . . . , 187 (27)

Additionally, a punctured code with data rate of 8/26 may be generated by the byte-code encoder 125 by not generating the smallest intrinsic data value packet M_{ABCDEFGH}, or another packet generated from only redundant packets.

As described above, a byte-code encoder may be configured to produce certain encoding code rates based on the number of codewords or packets used and the number of codewords or packets formed through a single encoding process. In addition, more complicated code rates may be constructed using particular arrangements of the previously described code rate encoders as building blocks or constituent code rate encoders. Further, additional processing blocks may be included to form a concatenated byte-code encoder. For example, a concatenated byte-code encoder may use additional interleaving blocks between constituent byte-code encoders in addition to redundancy to improve the ruggedness of the data stream produced. Various embodiments of redundant and code enhanced staggercasting transmission methods will be described below.

After encoding, the data is coupled to a packet deinterleaver 130. The packet deinterleaver 130 takes the bytes from the resulting SCBC codewords for the original group of packets in a column-by-column order, and outputs the bytes in a row by row order. The original packets are reconstituted and new packets are created from the parity bytes of the SCBC codewords. Each packet corresponds to a common GF(256) symbol location in all the created SCBC codewords. The number of packets created in each code frame is nSCBC, where the first kSCBC packets are the original data packets and the last (nSCBC−kSCBC) packets are parity packets.

The data is then coupled to the MPEG TS header modifier 135 where the MPEG headers are modified. The MPEG TS header modifier may modify the packet Identifier (PID) of the MPEG transport stream headers to indicate the code rate used by the error correction scheme. The code rates is expressed as a fraction of the original number of data bytes over the total number of data bytes used. For example, in a 12/52 rate mode, which supplements 12 data bytes with 40 parity bytes, each group of 12 bytes uses one R=½ Encoder, and two R= 12/26 Encoders, with each 12/26 Encoder using two R=⅔ Encoders and one 27/26 puncture, results in a 12/52 rate mode The R=27/26 puncture is performed in such away that the last byte of the 27 bytes is dropped. Two Data Blocks are used to transmit 12 MPEG TS packets under the 12/52 Rate Mode. The 12/26 rate mode supplements 12 data bytes with 14 parity bytes, each group of 12 data bytes uses two R=⅔ Encoders, and one R=27/26 puncture, results in a 12/26 rate mode. The R=27/26 puncture shall be performed in such a way that the last byte of the 27 bytes is dropped. One Data Block is used to transmit 12 MPEG TS packets under the 12/26 Rate Mode. The 17/26 rate mode supplements 17 data bytes with 9 parity bytes, each group of 17 data bytes group uses one R=⅔ Encoder to supplement 16 data bytes with 8 parity bytes, and one R=½ Encoder to supplement 1 data byte with 1 parity byte, results in a 17/26 rate mode. One Data Block is used to transmit 17 MPEG TS packets under the 17/26 Rate Mode. The 24/208 rate mode supplements 24 data bytes with 184 parity bytes, each group of 24 data bytes uses 24 R=¼ Encoders, and eight 12/26 Encodes, results in a 24/208 rate mode. The R= 27/26 puncture shall be performed in such a way that the last byte of the 27 bytes is dropped. Eight Data Blocks are used to transmit 24 MPEG TS packets under the 24/208 Rate Mode.

Each packet utilizing the MPEG protocol typically contains a packet identification portion or PID. The current system allows for over 8600 possible unique identification elements, and at present, only 50 are used. The PID is typically one or more bytes of information used for identifying the type of data in the packet. At present many of the PID portions of the bits remain reserved and unused. These PIDs can be used to identify a specific error correction code rate that will be imposed on the packet. Certain rules based on MPEG protocol should be maintained in order to assure the PID is properly identified by any receiving system. A three-byte header 440 contains a 13-bit packet identifier (PID) identifying the packet as part of a mobile/handheld transmission. The headers 440 of MPEG packets from the ATSC-M/H stream are modified after packet-deinterleaving to contain packet identifiers (PIDs) that are not recognized by legacy ATSC A/53 receivers. Thus, a legacy receiver should ignore the ATSC-M/H specific data, providing backward compatibility.

This data is then coupled to the Preamble packet inserter 140, where preamble packets consisting of consecutive MPEG packets are formed into a preamble block. The MPEG packets are formed with a valid MPEG header with data bytes generated from a PN generator (not shown). The number of data bytes generated from the PN generator varies with the code rate used, for example, 184 data bytes are generated in 12/52 rate mode to result in a total of 2208 bytes of PN data. According to an exemplary embodiment, the PN generator is a 16-bit shift register with 9 feedback taps. 8 of the shift register outputs are selected as the output byte. ATSC M/H packets are placed in between Preamble blocks in Data Blocks. Every Data Block contains 26 ATSC M/H encoded packets that have the same coding or 26 ATSC A/53 encoded packets. Once the preamble packets have been inserted 140, the ATSC M/H stream has been formed.

The ATSC-M/H data stream is then processed by the legacy ATSC A/53 path 145, including data randomizer 150, Reed-Solomon encoder 155, byte interleaver 160, 12-1 trellis encoder 165, sync insertion 170, pilot insertion 175, and modulation 180. In the data randomizer 150, each byte value is changed according to known pattern of pseudo-random number generation. This process is reversed in the receiver in order to recover the proper data values. With the exception of the segment and field syncs, it is desirable for the 8-VSB bit stream to have a completely random, noise-like nature to afford the transmitted signal frequency response must have a flat noise-like spectrum in order to use the allotted channel space with maximum efficiency.

The data is then coupled to the Reed-Solomon encoder 155, where Reed-Solomon (RS) coding provides additional error correction potential at the receiver through the addition of additional data to the transmitted stream. In an exemplary embodiment, the RS code used in the VSB transmission system is a t=I0 (207, 187) code. The RS data block size is 187 bytes, with 20 RS parity bytes added for error correction. A total RS block size of 207 bytes is transmitted per RS code word. In creating bytes from the serial bit stream, the MSB shall be the first serial bit and the 20 RS parity bytes are sent at the end of the data block or RS code word.

The byte interleaver 160 then processes the output of the Reed-Solomon encoder 155. Interleaving is a common technique for dealing with burst errors that can occur during transmission. Without interleaving, a burst error could have a large impact on one particular segment of the data, thereby rendering that segment uncorrectable. If the data is interleaved prior to transmission, however, the effect of a burst error can be effectively spread across multiple data segments. Rather than large errors being introduced in one localized segment that cannot be corrected, smaller errors may be introduced in multiple segments that are each separately within the correction capabilities of forward error correction, parity bit, or other data integrity schemes. For instance, a common (255, 223) Reed-Solomon code will allow correction of up to 16 symbol errors in each code word. If the Reed-Solomon coded data is interleaved before transmission, a long error burst is more likely to be spread across multiple codewords after deinterleaving, reducing the chances that more than the correctable 16 symbol errors are present in any particular codeword.

The interleaver employed in a VSB transmission system is a 52 data segment (intersegment) convolutional byte interleaver. Interleaving is provided to a depth of about ⅙ of a data field (4 ms deep). Only data bytes are interleaved. The interleaver is synchronized to the first data byte of the data field. Intrasegment interleaving is also performed for the benefit of the trellis coding process.

The signal is then coupled to the Trellis encoder 165. Trellis coding is another form of Forward Error Correction. Unlike Reed-Solomon coding, which treats the entire MPEG-2 packet simultaneously as a block, trellis coding is an evolving code that tracks the progressing stream of bits as it develops through time. Accordingly, Reed-Solomon coding is known as a form of block code, while trellis coding is a convolutional code.

In ATSC trellis coding, each 8-bit byte is split up into a stream of four, 2-bit words. In the trellis coder, each 2-bit word that arrives is compared to the past history of previous 2-bit words. A 3-bit binary code is mathematically generated to describe the transition from the previous 2-bit word to the current one. These 3-bit codes are substituted for the original 2-bit words and transmitted over-the-air as the eight level symbols of 8-VSB (3 bits=8 combinations or levels). For every two bits that go into the trellis coder, three bits come out. For this reason, the trellis coder in the 8-VSB system is said to be a ⅔ rate coder. The signaling waveform used with the trellis code is an 8-level (3 bit) one-dimensional constellation. The transmitted signal is referred to as 8 VSB. A 4-state trellis encoder shall be used.

In an exemplary embodiment, trellis code intrasegment interleaving is used. This uses twelve identical trellis encoders and precoders operating on interleaved data symbols. The code interleaving is accomplished by encoding symbols (0, 12, 24, 36 . . . ) as one group, symbols (1, 13, 25, 37, . . . ) as a second group, symbols (2, 14, 26, 38, . . . ) as a third group, and so on for a total of 12 groups.

Once the data has been trellis encoded, it is coupled to the sync inserter 170. The sync inserter 170 is a multiplexer which inserts the various synchronization signals (Data Segment Sync and Data Field Sync). A two-level (binary) 4-symbol Data Segment Sync is inserted into the 8-level digital data stream at the beginning of each Data Segment. The MPEG sync byte is replaced by Data Segment Sync. In an exemplary embodiment using ATSC transmission standards, a complete segment shall consist of 832 symbols: 4 symbols for Data Segment Sync, and 828 data plus parity symbols. The same sync pattern occurs regularly at 77.3 s intervals, and is the only signal repeating at this rate. Unlike the data, the four symbols for Data Segment Sync are not Reed-Solomon or trellis encoded, nor are they interleaved. The ATSC segment sync is a repetitive four symbol (one byte) pulse that is added to the front of the data segment and replaces the missing first byte (packet sync byte) of the original MPEG-2 data packet. Correlation circuits in the 8-VSB receiver home in on the repetitive nature of the segment sync, which is easily contrasted against the background of completely random data. The recovered sync signal is used to generate the receiver clock and recover the data. Segment syncs are easily recoverable by the receiver because of their repetitive nature and extended duration. Accurate clock recovery can be had at noise and interference levels well above those where accurate data recovery is impossible allowing for quick data recovery during channel changes and other transient conditions.

After sync insertion, the signal is coupled to the pilot insertion where a small DC shift is applied to the 8-VSB baseband signal causing a small residual carrier to appear at the zero frequency point of the resulting modulated spectrum. This ATSC pilot signal gives the RF PLL circuits in the 8-VSB receiver a signal to lock onto that is independent of the data being transmitted. The frequency of the pilot is the same as the suppressed-carrier frequency. This may be generated by a small (digital) DC level (1.25) added to every symbol (data and sync) of the digital baseband data plus sync signal (+I, +3, +5, +7). The power of the pilot is typically 11.3 dB below the average data signal power.

After the pilot signal is inserted, the data is coupled to the modulator 180. The modulator amplitude modulates the 8 VSB baseband signal on an intermediate frequency (IF) carrier. With traditional amplitude modulation, we generate a double sideband RF spectrum about our carrier frequency, with each RF sideband being the mirror image of the other. This represents redundant information and one sideband can be discarded without any net information loss. In 8 VSB modulation, the VSB modulator receives the 10.76 Msymbols/s, 8-level trellis encoded composite data signal (pilot and sync added). The ATV system performance is based on a linear phase raised cosine Nyquist filter response in the concatenated transmitter and receiver, as shown in FIG. 12. The system filter response is essentially flat across the entire band, except for the transition regions at each end of the band. Nominally, the roll-off in the transmitter shall have the response of a linear phase root raised cosine filter.

The transmission system includes operation for mobile and portable devices in a burst mode of transmission. Several key advantages of operating in burst mode, are described throughout the above document and include ability to be received by a new class of devices while still maintaining backward compatibility. These new classes of devices require a lower level of video resolution than is found in the existing broadcast standard, and can therefore also allow higher coding and compression, as well as other features including working in the presence of higher noise levels. An additional advantage of burst mode types of operation is focused on the potential device power savings by focusing use of the device only when signals intended for the device or to be received.

Burst mode operations such as those described may take advantage of time periods during which high data transmission of a signal is not required in order to maintain full performance of a legacy system and receiver. Burst mode operation may be based on processing signals based on a so-called new information processing rate, which may change depending on the current broadcast signal characteristics.

Backward compatibility with the legacy system is maintained by focusing the burst mode operations at a data packed level by introducing information for new program identifiers. The new program identifiers allow the new class of equipment to recognize the data, without affecting the operation of existing equipment. Further legacy support exists by including an Overlay structure in order to maintain legacy signal transmission operation during certain burst mode profiles.

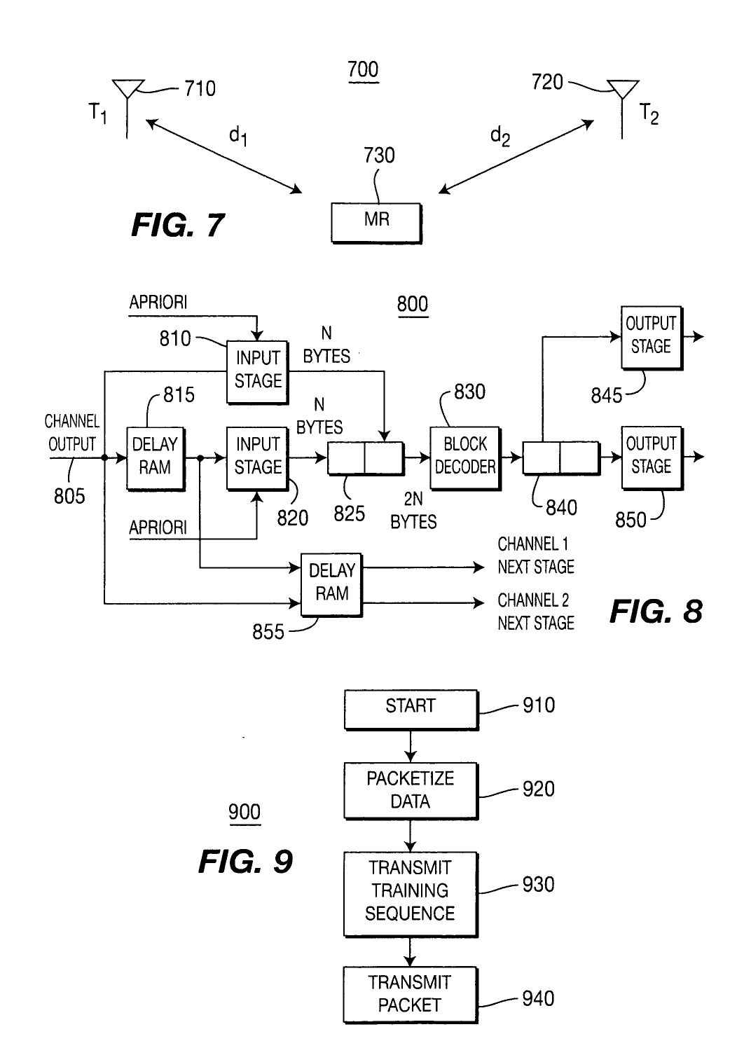

Taking advantage of the full redundancy of the systematic data and non-systematic data and the ability of the signal to be recovered from either of the totally separable codewords, adding frequency or special diversity as well as time diversity can increase the probability of reception by the mobile device. This will be discussed further in the discussions of FIG. 7.

Referring to FIG. 2, a block diagram of an embodiment of a portion of an exemplary mobile/handheld data stream 200 of the present disclosure is shown. 26 ATSC M/H coded packets are grouped into 1 Data Block. In legacy ATSC transmission every Data Block typically has the same coding, although this is not physically required. Preamble blocks are two blocks long and have 52 ATSC M/H coded packets. The very first MPEG packet following the Preamble block is a control packet that contains system information. Following randomization and forward error correction processing, the data packets are formatted into Data Frames for transmission and Data Segment Sync and Data Field Sync are added.

The ATSC-M/H data stream 200 is made up of bursts having a Preamble block 210 followed by a predetermined number of Data Blocks 230 appropriate for the selected data rate mode. According to the exemplary embodiment, each Data Block 230 consists of 26 MPEG packets. Each Data Frame consists of two Data Fields, each containing 313 Data Segments. The first Data Segment of each Data Field is a unique synchronizing signal (Data Field Sync) and includes the training sequence used by the equalizer in the receiver. The remaining 312 Data Segments each carry the equivalent of the data from one 188-byte transport packet plus its associated FEC overhead. The actual data in each Data Segment comes from several transport packets because of data interleaving. Each Data Segment consists of 832 symbols. The first 4 symbols are transmitted in binary form and provide segment synchronization. This Data Segment Sync signal also represents the sync byte of the 188-byte MPEG-compatible transport packet. The remaining 828 symbols of each Data Segment carry data equivalent to the remaining 187 bytes of a transport packet and its associated FEC overhead. These 828 symbols are transmitted as 8-level signals and therefore carry three bits per symbol. Thus, 828×3=2484 bits of data are carried in each Data Segment, which is the requirement to send a protected transport packet:

The ATSC M/H data stream consists of a sequence of blocks, each block consisting of 26 packets of either the legacy VSB A/53 system or ATSC M/H system. The ATSC M/H data stream is made up of bursts of blocks that each burst has a Preamble block followed by Nb Data Blocks, where Nb is a system variable parameter and a function of the overall ATSC M/H data rate to be transmitted. Each Data Block is encoded at one of the defined ATSC M/H rate modes. This rate mode is applied to the entire Data Block. For each burst of blocks, the Data Blocks are delivered such that the highest coded FEC rates (i.e. the lowest fractional numbers) in the burst of blocks will be delivered earliest and the lowest coded FEC rates (i.e. the highest fractional numbers) will be delivered the latest such that starting from a Preamble block, any following Data Blocks will have equal or less robustness than the current Data Block. ATSC A/53 8VSB coded legacy Data Blocks of 26 packets can be placed at one or more block for legacy overlay operation.

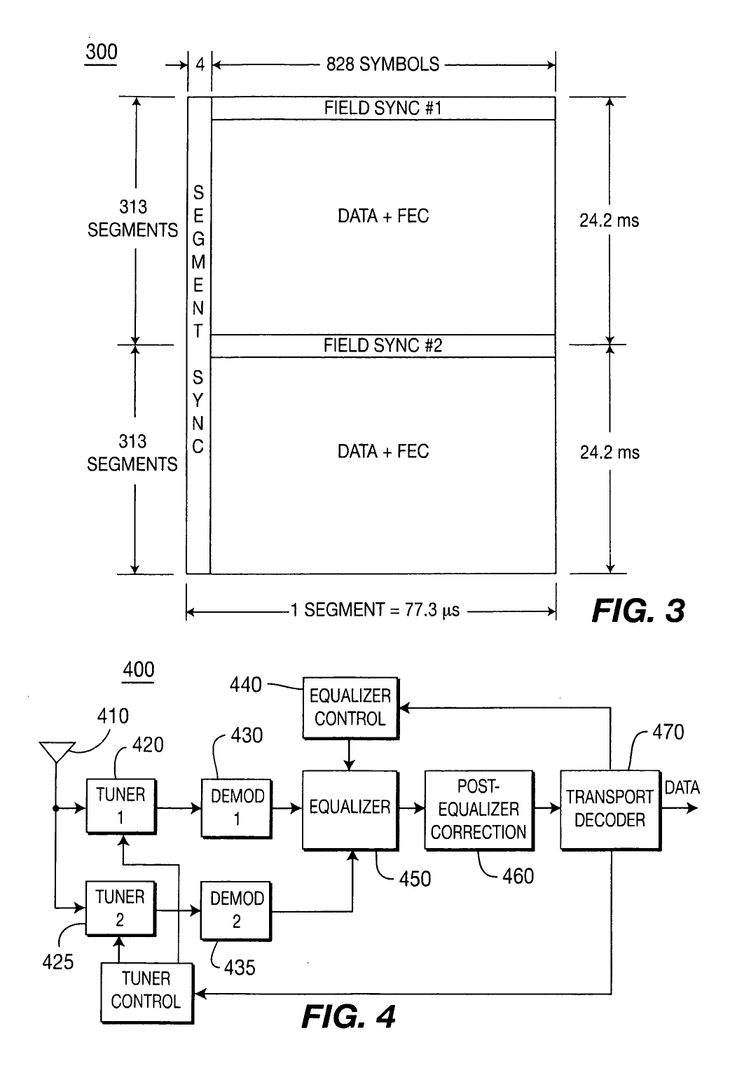

Turning now to FIG. 3, a data frame 300 is shown according to the present invention is shown. The data frame 300 shown is organized for transmission where each Data Frame consists of two Data Fields, each containing 313 Data Segments. The first Data Segment of each Data Field is a unique synchronizing signal (Data Field Sync) and includes the training sequence used by the equalizer in the receiver. The remaining 312 Data Segments each carry the equivalent of the data from one 188-byte transport packet plus its associated FEC overhead. The actual data in each Data Segment comes from several transport packets because of data interleaving. Each Data Segment consists of 832 symbols. The first 4 symbols are transmitted in binary form and provide segment synchronization. This Data Segment Sync signal also represents the sync byte of the 188-byte MPEG-compatible transport packet. The remaining 828 symbols of each Data Segment carry data equivalent to the remaining 187 bytes of a transport packet and its associated FEC overhead. These 828 symbols are transmitted as 8-level signals and therefore carry three bits per symbol. Thus, 828×3=2484 bits of data are carried in each Data Segment, which exactly matches the requirement to send a protected transport packet:

187 data bytes+20 RS parity bytes=207 bytes

207 bytes×8 bits/byte=1656 bits

⅔ rate trellis coding requires 3/2×1656 bits=2484 bits.

The exact symbol rate is given by equation 1 below:

Sᵣ (MHz)=4.5/286×684=10.76 . . . MHz (1)

The frequency of a Data Segment is given in equation 2 below:

f_{seg}=Sᵣ/832=12.94 . . . ×10³ Data Segments/s. (2)

The Data Frame rate is given by equation (3) below:

f_{frame}=f_{seg}/626=20.66 . . . frames/s. (3)

The symbol rate Sᵣ and the transport rate Tᵣ shall be locked to each other in frequency.

The 8-level symbols combined with the binary Data Segment Sync and Data Field Sync signals is used to suppressed-carrier modulate a single carrier. Before transmission, however, most of the lower sideband shall be removed. The resulting spectrum is flat, except for the band edges where a nominal square root raised cosine response results in 620 kHz transition regions. At the suppressed-carrier frequency, 310 kHz from the lower band edge, a small pilot is added to the signal as described previously.

Turning now to FIG. 4, an embodiment of a terrestrial broadcast receiver 400 for mobile/handheld reception of the present disclosure is shown. The receiver 400 comprises a signal receiving element 410, a first tuner 420, a second tuner 425, a first pre-equalizer demodulator 430, a second pre-equalizer demodulator 430, a equalizer controller 440, an equalizer 450, a post-equalizer correction processor 460, a transport decoder 470 and a tuner controller 480.

The signal receiving element 410 is operative to receive signals including audio, video, and/or data signals (e.g., television signals, etc.) from one or more signal sources, such as a terrestrial broadcast system and/or other type of signal broadcast system. According to an exemplary embodiment, signal receiving element 410 is embodied as an antenna such as a log periodic antenna, but may also be embodied as any type of signal receiving element. The antenna 410, of this exemplary embodiment, is operative to receive ATSC M/H terrestrially transmitted audio, video, and data signals over a frequency bandwidth. ATSC signals are generally transmitted over the frequency range of 54 to 870 MHz, with a bandwidth of approximately 6 MHz per channel. Sub channels may be time multiplexed. The signal is coupled from the antenna vie a transmission line such as a coaxial cable or printed circuit board trace.

The first and second tuners 420, 425 are operative to perform a signal tuning function responsive to a control signal from the tuner controller 480. According to an exemplary embodiment, the each tuner 420, 425 receives a different time, or frequency diverse RF signal from either one or a plurality of antennas 410, and performs the signal tuning function by filtering and frequency down converting (i.e., single or multiple stage down conversion) the RF signal to thereby generate an intermediate frequency (IF) signal. The RF and IF signals may include audio, video and/or data content (e.g., television signals, etc.), and may be of an analog signal standard (e.g., NTSC, PAL, SECAM, etc.) and/or a digital signal standard (e.g., ATSC, QAM, QPSK, etc.). Each tuner 420 is operative to convert the received ATSC M/H signal from the carrier frequency to an intermediate frequency. For example, the tuner may convert a 57 MHz signal received at the antenna 410 to a 43 MHz IF signal. The Pre-Equalizer Demodulator 430 is operative to demodulate the IF signal from the Tuner 420, to a baseband digital stream. Demodulator 435 is operative to demodulate the IF signal from tuner 425. The baseband digital streams are then coupled to the equalizer.

The tuner controller 480 is operative receive instructions from the transport decoder 470 in response to the signal level and frequency of the tuned channel or a desired tuned channel. The tuner controller 480 generates a control signal in response to these received instructions to control the tuner 420, 425 operation.

The equalizer controller 440 is operative to generate an error term in response to the decoded data received from the demulators 430, 435. This provides the ability for a data directed equalizer. The equalizer controller 440 estimates the error between the received data and the decoded data and generates an error term. The error term is fed to the equalizer 450 to be minimized.

The equalizer 450 is operative to receive the tuned and demodulated MPEG stream from the pre-equalizer demodulators 430, 435 and calculates equalizer coefficients which are applied to an equalization filter within the equalizer to produce an error free signal. The equalizer 450 is operative to compensate for transmission errors, such as attenuation and intersymbol interference. The equalizer comprises a matched filter which performs roll off filtering which is operative to cancel the intersymbol interference. During the equalizer training period, a previously chosen training signal is transmitted through the channel and a properly delayed version of this signal, that is prestored in the receiver, is used as a reference signal. The training signal is usually a pseudo-noise sequence long enough to allow the equalizer to compensate for the channel distortions. The equalizer according to an exemplary embodiment of the present invention is operative to store a plurality of pseudo-noise sequences, wherein each pseudo-random sequence corresponds to a code rate. When the equalizer 450 receives the pseudorandom sequence training signal, the equalizer compares a portion of the received sequence with the plurality of stored sequences. When a match is made, the code rate associated with the received sequence is used by the decoder to decode the data received after the training sequence.

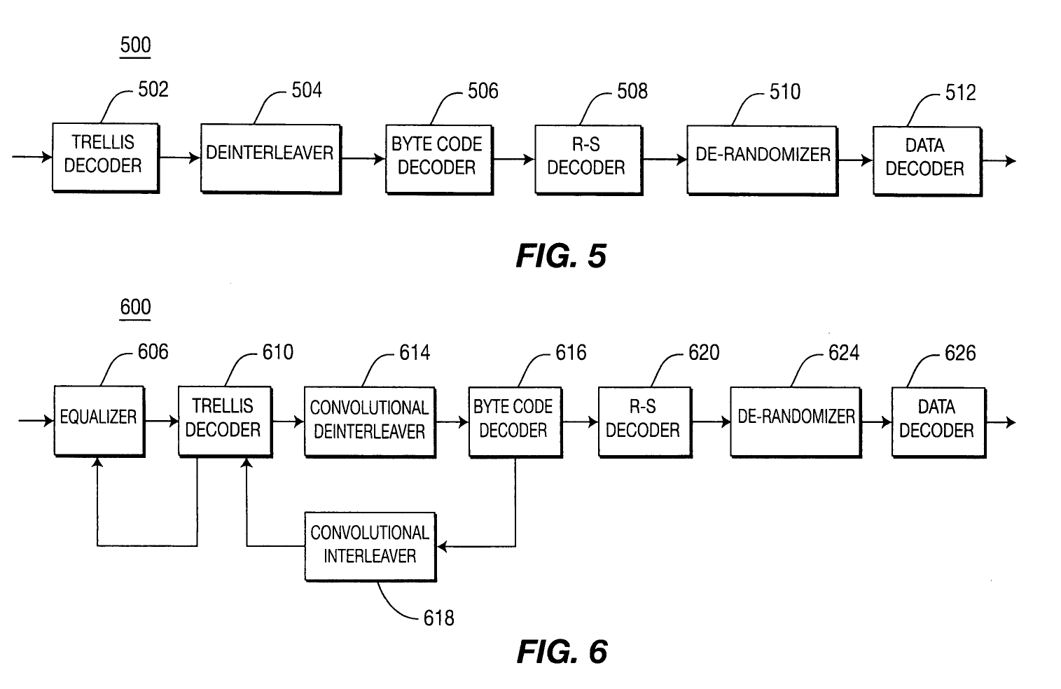

The post-equalizer correction processor 460 and transport decoder 470 are operative to perform error correction and to decode the MPEG data stream. These elements are shown and discussed in detail in FIGS. 5 and 6.

The receiver may be configured to operate with a single tuner and demodulator by time sharing the tuner to receive different frequencies and different times. Alternately, the tuner may be configured with a bandwidth wide enough to receive two signals simultaneously such that both signals may be tuned to different IF frequencies and each of these IF frequencies can be simultaneously processed or time multiplexed processed by a demodulator. In a single tuner, using either time or frequency diversity the packet combination is not done in the equalizer, but is instead done in the code as the equalizer must follow the transmitted signals. This gives three possibilities of receiving the packet correctly, the first packet correctly, the second packet correctly, or the combination after the byte decoder correctly. When coding is being used to combine the packets as opposed to receiving a single packet, it decreases the minimum amount of signal to noise ratio required to receive a virtually error free signal. For example, in a ½ code rate, the minimum threshold is decreased from 15 dB for a single packet with no coding to 7 dB for 2 packets with coding and 3.5 dB for 4 packets with coding.

Turning now to FIG. 5, a block diagram of an embodiment of a decoder 500 used in a receiver system is shown. Decoder 500 includes circuitry that is adapted to use redundant packets, such as the non-systematic packets in a data stream as described above, to aid in decoding data received by the receiver. Decoder 500 is also generally capable of decoding data that has been encoded using the legacy or existing A53 standard.

In decoder 500, following initial tuning, demodulation, and processing by other circuits (FIG. 4) a trellis decoder 502 receives the incoming signal. The trellis decoder 502 is connected to a convolutional de-interleaver 504. The output of the convolutional de-interleaver 504 is connected to a byte-code decoder 506. The byte-code decoder 506 has an output that is connected to a Reed-Solomon decoder 508. The output of the Reed-Solomon decoder 508 is connected to a de-randomizer 510. The de-randominizer 510 output is connected to a data decoder 512. The data decoder 512 provides an output signal for use in the remaining portion of the receiver system such as video display or audio reproduction.

In accordance with the existing or legacy A53 standard, the trellis decoder 502 includes a signal de-multiplexer, twelve ⅔-rate trellis decoders and a signal multiplexer. The de-multiplexer distributes the digital samples among the twelve ⅔-rate trellis decoders and the multiplexer multiplexes the estimates generated byte each of the twelve ⅔-rate trellis decoders. A de-interleaver 504, such as a convolutional interleaver, de-interleaves the stream of trellis-decoded bit estimates, producing sequences or packets arranged to include 207 bytes. The packet arrangement is performed in conjunction with the determination and identification of the location of the synchronization signals, not shown. A Reed-Solomon error correction circuit 508 considers each sequence of 207 bytes produced by the de-interleaver 504 as one or more codewords and determines if any bytes in the codewords or packets were corrupted due to an error during transmission. The determination is often performed by calculating and evaluating a set of syndromes or error patterns for the codewords. If corruption is detected, the Reed-Solomon error correction circuit 508 attempts to recover the corrupted bytes using the information encoded in the parity bytes. The resulting error-corrected data stream is then de-randomized by a de-randomizer 510 and thereafter provided to a data decoder 512 that decodes the data stream in accordance with the type of content being transmitted. Typically, the combination of the trellis decoder 502, the de-interleaver 504, the Reed-Solomon decoder 508, and the de-randomizer 510 are identified as an 8-VSB decoder within a receiver. It is important to note that, in general, the typical receiver for receiving signals compliant with the legacy A53 standard performs the receiving process in the reverse order of the transmitting process.

The received data, in the form of bytes of data in data packets, is decoded by trellis decoder 502 and de-interleaved by de-interleaver 504. The data packets may include 207 bytes of data and further may be grouped in groups or 24, 26, or 52 packets. The trellis decoder 502 and de-interleaver 504 are capable of processing incoming legacy format data as well as byte-code encoded data. Based on a predetermined packet transmission sequence that is also known by the receiver, the byte-code decoder 506 determines if the packet is a packet included in a byte-code encoded or robust data stream. If the received packet is not from the byte-code encoded data stream then the received packet is provided to the Reed-Solomon decoder 508 without any further processing in byte-code decoder 506. Byte code decoder 506 may also include a de-randomizer that removes the known sequence of constants multiplied by or added to the data stream during encoding. It is important to note that a rugged data stream includes both systematic packets and bytes that are identical to the original data and non-systematic packets and bytes that contain redundant data.

If the byte-code decoder 506 determines that the received is a byte-code encoded packet belonging to robust or rugged data stream, the packet may be decoded along with other packets comprising the same data stream. In one embodiment, byte-code encoded packets of the same data stream are decoded by multiplying each byte within the packet by the inverse of the value of the element that was used to develop the byte-coded packet. The decoded values of the bytes of the non-systematic packet are compared to the values of the bytes of the systematic packet and the values of any bytes in the two packets that are not identical may be erased (i.e., set to zero) in the systematic packet or may be replaced by the information in the non-systematic packet. The systematic packet with error bytes erased may thereafter be decoded using Reed-Solomon decoding performed in Reed-Solomon decoder 508. Further description of other embodiments of byte-code decoders will be discussed below.

Byte code decoder 506 may also be adapted to operate as a block coder for decoding signals encoded as shown in FIG. 1. For instance, byte code decoder 506 may include a packet interleaver similar to packet interleaver 120 and a packet deinterleaver similar to packet deinterleaver 130. Additionally, the byte code encoder function may be adapted to decode a GF(256) Serial Concatenated Block Coded (SCBC) signal. The byte code decoder 506 may further include an identifier block used for identifying data encoded for mobile or ATSC M/H reception and/or identification of a-priori training packets. Additionally, the identifier block may include a packet identifier block to determine, for example, if the headers in the incoming packets include a PID used for mobile reception.

It is important to note that in a preferred encoder byte-code encoding precedes the Reed-Solomon encoding of data packets. However, in decoder 500 shown here, the incoming data is byte-code decoded before being the Reed-Solomon decoded. The re-ordering is possible because both the byte-code operation and Reed-Solomon code operation are linear over the Galois Field(256) used in the A53 standard, and linear operators are commutative in a Galois Field. It is advantageous to do block decoding first before the Reed Solomon because there are soft decoding algorithms which make it practical to have an iterative decoding algorithm. The importance of the re-ordering is important because the byte-code encoding provides a soft decoding algorithm, which then makes possible iterative decoding or turbo decoding, which has higher reliability for recovering errors in the received signal. As a result, performing byte-code decoding prior to Reed-Solomon decoding results in improved receiver performance as measured in terms of bit-error rate and signal to noise ratio.

Turning now to FIG. 6, a block diagram of another embodiment of a decoder 600 used in a receiver is shown. Decoder 600 includes additional circuitry and processing for receiving and decoding signals that have been adversely affected by transmission of the signal over a transmission medium such as electromagnetic waves over the air. Decoder 600 is capable of decoding both a rugged data stream as well as a legacy data stream.

In decoder 600, the incoming signal, following initial processing, is provided to equalizer 606. Equalizer 606 is connected to trellis decoder 610, which provides two outputs. A first output from trellis decoder 610 provides feedback and is connected back as a feedback input to equalizer 606. The second output from trellis decoder 610 is connected to a convolutional de-interleaver 614. The convolutional de-interleaver 614 is connected to a byte-code decoder 616, which also provides two outputs. A first output from byte-code decoder 616 is connected back as a feedback input to trellis decoder 610 through a convolutional interleaver 618. The second output from byte-code decoder 616 is connected to a Reed-Solomon decoder 620. The output of the Reed-Solomon decoder 620 is connected to de-randomizer 624. The output of the de-randomizer 624 is connected to a data decoder 626. Reed-Solomon decoder 620, de-randomizer 624, and data decoder 626 are connected, and functionally operate, in a manner similar to Reed-Solomon, de-randomizer, and data decoder blocks described in FIG. 5 and will not be further described here.

An input signal from the front end processing (e.g. antenna, tuner, demodulator, A/D converter) of the receiver (not shown) is provided to equalizer 606. Equalizer 606 processes the received signal to completely or partially remove the transmission channel effect in an attempt to recover the received signal. The various removal or equalization methods are well known to those skilled in the art and will not be discussed here. Equalizer 506 may include multiple sections of processing circuitry including a feed-forward equalizer (FFE) section and a decision-feedback-equalizer (DFE) section.

The equalized signal is provided to trellis decoder 610. The trellis decoder 610 produces, as one output, a set of decision values that are provided to the DFE section of equalizer 606. The trellis decoder 610 may also generate intermediate decision values that are also provided to the DFE section of equalizer 606. The DFE section uses the decision values along with intermediate decision values from the trellis decoder 610 to adjust values of filter taps in equalizer 606. The adjusted filter tap values cancel interference and signal reflections that are present in the received signal. The iterative process allows equalizer 606, with the assistance of feedback from trellis decoder 610, to dynamically adjust to a potential changing signal transmission environment conditions over time. It is important to note that the iterative process may occur at a rate similar to incoming data rate of the signal, such as 19 Mb/s for a digital television broadcast signal. The iterative process also may occur at a rate higher than the incoming data rate.

The trellis decoder 610 also provides a trellis decoded data stream to convolutional de-interleaver 614. Convolutional de-interleaver 614 operates similar to the de-interleaver described in FIG. 5 generates de-interleaved bytes organized within data packets. The data packets are provided to byte-code decoder 5616. As described above, packets that are not a part of a rugged data stream are simply passed through the byte-code decoder 616 to Reed-Solomon decoder 620. If the byte-code decoder 616 identifies a group of the packets as part of a rugged data stream, the byte-code decoder 616 uses the redundant information in the non-systematic packets to initially decode the bytes in the packets as described above.

Byte-code decoder 616 and the trellis decoder 610 operate in an iterative manner, referred to as a turbo-decoder, to decode the rugged data stream. Specifically, the trellis decoder 610 provides, after de-interleaving by convolutional de-interleaver 614, a first soft decision vector to the byte-code decoder 616 for each byte of the packets that are included in the rugged data stream. Typically, the trellis decoder 610 produces the soft decision as a vector of probability values. In some embodiments, each probability value in the vector is associated with a value that the byte associated with the vector may have. In other embodiments, the vector of probability values is generated for every half-nibble (i.e., two bits) that is contained in the systematic packet because the ⅔-rate trellis decoder estimates two-bit symbols. In some embodiments the trellis decoder 610 combines four soft decisions associated with four half-nibbles of a byte to produce one soft-decision that is a vector of the probabilities of values that the byte may have. In such embodiments, the soft-decisions corresponding to the byte is provided to the byte-code decoder 616. In other embodiments, the byte-code decoder separates a soft-decision regarding a byte of the systematic packet into four soft-decision vectors, wherein each of the four soft-decisions is associated with a half-nibble of the byte.

The byte-code decoder 616 uses the soft decision vector associated with the bytes comprising packets of the rugged data stream to produce a first estimate of the bytes that comprise the packets. The byte-code decoder 616 uses both the systematic and the non-systematic packets to generate a second soft decision vector for each byte of packets comprising the rugged stream and provides the second soft-decision vector to the trellis decoder 610, after re-interleaving by convolutional interleaver 618. The trellis decoder 610 thereafter uses the second soft-decision vector to produce a further iteration of the first decision vector, which is provided to the byte-code decoder 616. The trellis decoder 610 and the byte-code decoder 616 iterate in this fashion until the soft-decision vector produced by the trellis decoder and byte-code decoder converge or a predetermined number of iterations are undertaken. Thereafter, the byte-code decoder 616 uses the probability values in the soft-decision vector for each byte of the systematic packets to generate a hard decision for each byte of the systematic packets. The hard decision values (i.e., decoded bytes) are output from the byte-code encoder 616 to Reed-Solomon decoder 620. The trellis decoder 610 may be implemented using a Maximum a Posteriori (MAP) decoder and may operate on either byte or half-nibble (symbol) soft decisions.

It is important to note that turbo-decoding typically utilizes iteration rates related to passing decision data between blocks that are higher than the incoming data rates. The number of possible iterations is limited to the ratio of the data rate and the iteration rate. As a result and to the extent practical, a higher iteration rate in the turbo-decoder generally improves the error correction results. In one embodiment, an iteration rate that is 8 times the incoming data rate may be used.

A soft input soft output byte-code decoder such as described in FIG. 6 may include vector decoding functions. Vector decoding involves grouping bytes of the data including systematic and non-systematic bytes. For example, for a rate ½ byte code encoded stream, 1 systematic and 1 non-systematic byte will be grouped. The two bytes have over 64,000 possible values. The vector decoder determines or estimates a probability for each of the possible values of the two bytes and creates a probability map. A soft decision is made based on a weighting the probabilities of some or all of the possibilities and the Euclidean distance to a possible codeword. A hard decision may be made when the error of the Euclidean distance falls below a threshold.

Byte-code decoders, as described in FIGS. 5 and 6 may decode a rugged data stream that has been encoded by the byte-code encoders described earlier, including encoding by simple byte-code encoders or concatenated byte-code encoders. The byte-code decoders in FIGS. 5 and 6 describe decoding a rugged data stream encoded by a simple or constituent byte-code encoder involving only a single encoding step. Concatenated byte-code decoding includes decoding the incoming codewords or bytes in more than one decoding step in addition to intermediate processing such as de-interleaving, de-puncturing, and re-insertion.

Referring to FIG. 7, an exemplary broadcast environment 700 according to the present invention is shown. A first transmitter 720, a second transmitter 720 and a mobile receiver 730 are shown. The first transmitter 710 is located at a distance d1 from the mobile receiver 730 and the second transmitter 720 is located at a distance d2 from the mobile receiver 730.

Taking advantage of the separable and redundant codewords, a first codeword can be transmitted from the first transmitter 710 and a second codeword can be transmitted from the second transmitter 720. This reduces the occurrence of total signal loss by varying the propagation paths and angles. These variations reduce the probability of total signal nulls or completely destructive multipath. Signal reception can further be improved by transmitting each codeword at a different frequency and/or at a different time.

This embodiment of spatial and frequency diversity may utilize the inherent “white space” between the existing broadcast channels in a coverage area, while not increasing the equalizer complexity of the current receiver. Such a proposed embodiment is also particularly well suited, though not limited to, burst mode transmission as is currently under consideration for advance broadcast transmission systems. In burst mode transmission, a single tuner in the receiver can still receive a complete transmission by receiving non-simultaneous content at multiple frequencies. A complete reception may be achieved by receiving only one of two or more bursts supplied from more than one source, including the main and secondary transmitters. Signal synchronization may be maintained through a number of known techniques including techniques already in use for SFN.

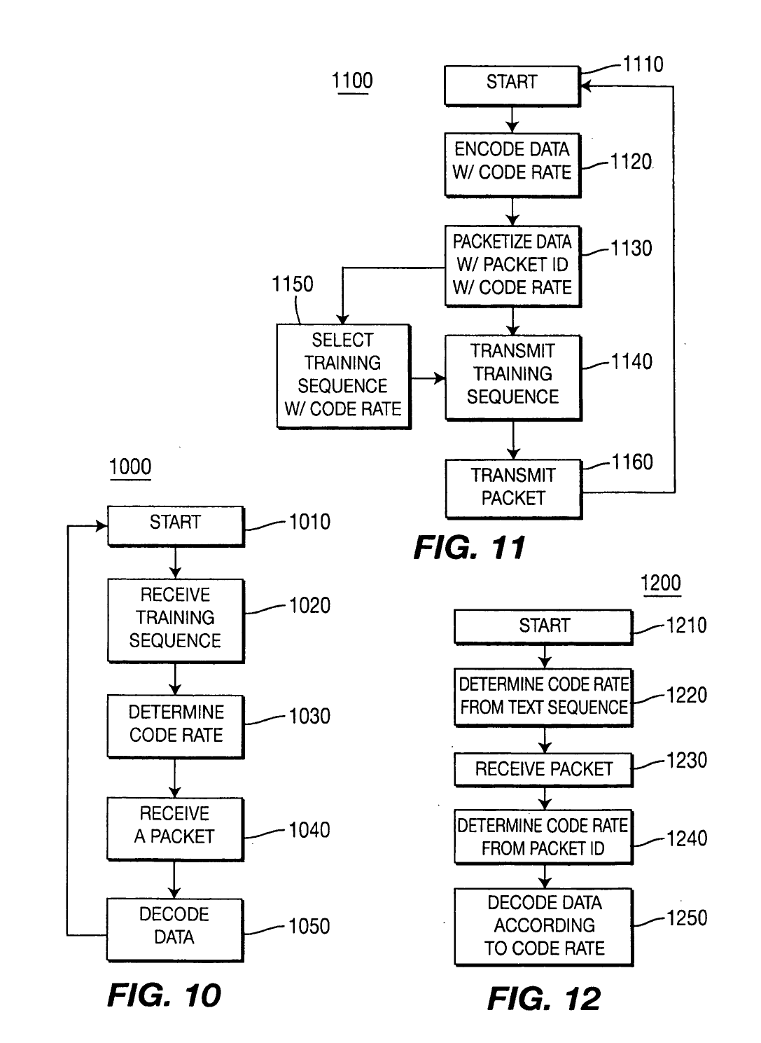

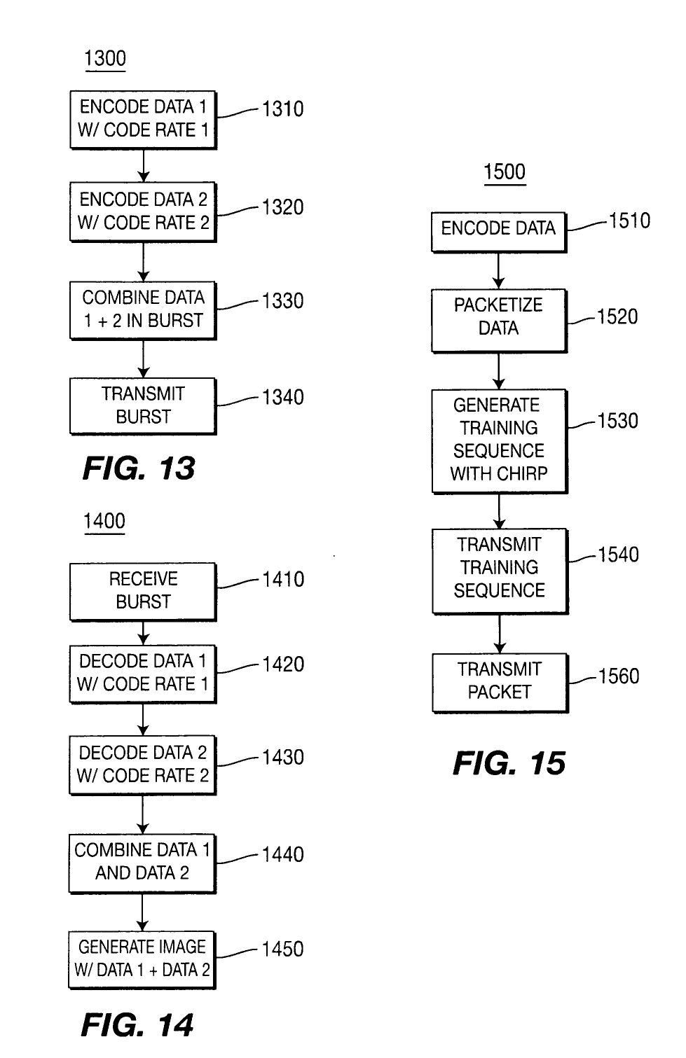

Referring to FIG. 8, an exemplary embodiment of a portion of a transmitter 800 according to the present invention is shown. The figure below illustrates an arrangement for a specific implementation of a code enhanced deeply interleaved staggercasting structure in the physical layer of a signal transmitting system. Implementation in a receiver would result in similar structures rearranged for decoding and demodulation as opposed to encoding and modulation. In operation, the processing involves identification and generation of information for redundant or staggercast operation. This content is received via the channel output 805. Next, the content is provided to a coder containing two or more parallel encoding branches suitable for nominally generating a standard coded burst mode signal. Next, each coding branch processes its supplied portion of the signal. Next, one branch is delayed by a delay RAM 815 by a predetermined amount. The delay amount may represent a number cycles of a signal such as field synchronization signal, and further may delay to an equivalent time representation of a future or subsequent burst transmission time. Each signal on each branched is encoded in their respective input stages 810, 820. The input stages may comprise legacy deinterlacing and packet deinterlacing. For time diversity signals, the undelayed coding branch signal may be combined 825 with a previously coded and delayed branch signal containing a portion of previously processed data content and the combination provided to the remaining portions of the transmitter. The combined data is then block decoded 830 and separated 840 into different output stages. Each output stage 845, 850 may combine legacy interleaving and legacy encoding. Processes for the receiver may be substantially similar and primarily reversed from the processes for a transmitter.

For spatially diverse or frequency diverse transmission, content is coupled from the channel input, before or after the delay RAM 815 and optionally coupled to another delay RAM 855. The content may then be coupled to further channels for transmission comprising operations as shown with respect to FIG. 1. One advantage of spatial and frequency diverse transmitters is using cooperative transmission. In this example, two television broadcasters, or one broadcaster with two transmitters or frequencies, can transmit the first broadcast packet on one transmitter and the cooperating broadcast redundant packet. Thus, each broadcaster transmits 2 packets, one burst and one redundant burst, but gains a diversity advantage by having their redundant packet transmitted on another frequency and/or another transmitter simply by transmitting the redundant burst of the cooperating broadcaster. Cooperative transmission gives the benefit of complete frequency diversity and possibly spatially diversity without increasing each cooperating transmitters data output or bandwidth.

Further, in addition to the inherent benefit associated with significant time interleaving of the data content and the relationship to operation in burst mode transmissions, each branch of modified code enhanced data may be transmitted on separate frequencies. In this manner, frequency diversity, in addition to time diversity, may be achieved. For example, a first burst containing a portion of the staggercast content, after code enhancing, may be provided or transmitted on a particular broadcast channel by a first broadcaster. A second burst containing a remaining portion of the staggercast content, after code enhancing, may be provided or transmitted at a later point in time and on a second broadcast channel, possibly by a second broadcaster. Each broadcast channel represents a different frequency spectrum of operation. The resultant operation further guarantees recovery of the original data content by introducing frequency diversity operation to the already inherent time diversity system.

While the present invention has been described in terms of a specific embodiment, it will be appreciated that modifications may be made which will fall within the scope of the invention. For example, various processing steps may be implemented separately or combined, and may be implemented in general purpose or dedicated data processing hardware. Furthermore, various encoding or compression methods may be employed for video, audio, image, text, or other types of data. Also, the packet sizes, rate modes, block coding, and other information processing parameters may be varied in different embodiments of the invention.

1. A method for encoding data comprising the steps of:
encoding said data to generate a packet and a redundant packet wherein each packet comprises said data; and
coupling said packet and said redundant packet to a transmitter.

2. The method of claim 1 wherein said packet and said redundant packet are coupled to different transmitters wherein the different transmitters are spatially diverse.

3. The method of claim 1 wherein the packet and the redundant packet are transmitted at different frequencies.

4. The method of claim 1 wherein the packet and the redundant packet are transmitted at different times.

5. A method of receiving a signal comprising the steps of:
receiving a first packet;
receiving a second packet, wherein the second packet is a redundant version of the first packet;
combining the first and second packets;
decoding the first and second packets.

6. The method of claim 5 wherein the first packet is received at a first frequency and the second packet is received at a second frequency.

7. The method of claim 5 wherein the first packet is received at a first time, and the second packet is received at a second time.

8. An apparatus comprising
an encoder for encoding a data to generate a packet and a redundant packet; and
an interface for coupling said packet to a first transmitter and said redundant packet to a second transmitter.

9. The apparatus of claim 8 wherein said packet is transmitted at a first frequency and said redundant packet is transmitted at a second frequency.

10. The apparatus of claim 8 wherein said packet is transmitted at a first time and said redundant packet is transmitted at a second time.

11. An apparatus comprising:
an interface for receiving a first packet and a second packet;
a decoder for decoding the first packet and the second packet to generate a first decoded packet and a second decoded packet;
a processor for combining the first decoded packet and the second decoded packet to generate a video signal.

12. The apparatus of claim 11 wherein the second packet is a redundant version of the first packet.

13. The apparatus of claim 11 wherein the first packet is received on a first frequency and the second packet is received at a second frequency.

14. The apparatus of claim 11 wherein the first packet is received at a first time and the second packet is received at a second time.
